(19) United States
(12) Patent Application Publication
(10) Pub. No.: US 2015/0044615 A1
(43) Pub. Date: Feb. 12, 2015

(54) DRAWING DATA GENERATING METHOD, PROCESSING APPARATUS, STORAGE MEDIUM, DRAWING APPARATUS, AND METHOD OF MANUFACTURING ARTICLE

(71) Applicant: CANON KABUSHIKI KAISHA, Tokyo (JP)

(72) Inventors: Kimitaka OZAWA, Utsunomiya-shi (JP); Isamu SETO, Utsunomiya-shi (JP)

(21) Appl. No.: 14/446,857

(22) Filed: Jul. 30, 2014

(30) Foreign Application Priority Data
Aug. 9, 2013 (JP) 2013-166993

(51) Int. Cl. H01J 37/317; G03F 7/20; G03F 7/30; H01J 37/302

(52) U.S. Cl. CPC H01J 37/3175; H01J 37/3177; H01J 37/3026; G03F 7/2037; G03F 7/30; H01J 2237/04924; H01J 2237/06308; H01J 2237/043
USPC 430/296; 250/492.22

(57) ABSTRACT

A method generates drawing data for performing drawing on a substrate with a plurality of charged particle beams based on pattern data representing a pattern to be drawn on the substrate. The method includes: a grouping step of grouping the plurality of charged particle beams into a plurality of groups based on a displacement amount of an irradiation position of each of the plurality of charged particle beams from target position thereof; and a generating step of generating the drawing data by changing the pattern data with respect to each of the plurality of groups based on the displacement amount of each of the plurality of charged particle beams.

### BACKGROUND OF THE INVENTION

1. Field of the Invention

The present invention relates to a drawing data generating method, a processing apparatus, a storage medium, a drawing apparatus, and a method of manufacturing an article.

2. Description of the Related Art

As a drawing apparatus used to manufacture a device such as a semiconductor integrated circuit, Japanese Patent Laid-Open No. 9-7538 discloses a drawing apparatus which performs drawing on a substrate with a plurality of charged particle beams (array of charged particle beams). However, in this drawing apparatus, the intervals between respective charged particle beams may deviate from predetermined values assumed in design owing to mechanical manufacturing errors of an aperture array, lens array, and projection optical system, oblique incidence of a charged particle beam with respect to an ideal central axis along with these errors, and the like. Variations in the intervals between charged particle beams can be corrected using a deflector, as a matter of course. However, it is difficult to construct one deflector for one charged particle beam in terms of the restriction of the apparatus space, the cost, and the like. Therefore, Japanese Patent No. 3940310 has proposed a method of compensating for the displacement of a pattern drawn by respective charged particle beams from a desired pattern by changing data of the pattern drawn by the respective charged particle beams.

In Japanese Patent No. 3940310, the number of charged particle beams is about 4,000. However, the number of charged particle beams is considered to increase (for example, 500,000 or more) in the future for higher throughput. In the drawing method of Japanese Patent No. 3940310, pattern data needs to be prepared for each of 500,000 or more charged particle beams, and a large-capacity memory is necessary to hold the pattern data. In the drawing method of Japanese Patent No. 3940310, the volume of the drawing apparatus may become an issue as the memory capacity increases.

### SUMMARY OF THE INVENTION

The present invention provides, for example, a drawing data generation method advantageous in terms of compatibility of drawing precision and drawing data amount.

The present invention in its one aspect provides a method of generating drawing data for performing drawing on a substrate with a plurality of charged particle beams based on pattern data representing a pattern to be drawn on the substrate, the method comprising: a grouping step of grouping the plurality of charged particle beams into a plurality of groups based on a displacement amount of an irradiation position of each of the plurality of charged particle beams from a target position thereof; and a generating step of generating the drawing data by changing the pattern data with respect to each of the plurality of groups based on the displacement amount of each of the plurality of charged particle beams.

Further features of the present invention will become apparent from the following description of exemplary embodiments with reference to the attached drawings.

### BRIEF DESCRIPTION OF THE DRAWINGS

FIG. 1 is a view showing an example of the arrangement of a drawing apparatus;

FIG. 2 is a flowchart showing a drawing method;

FIG. 3 is a view showing an irradiation position when some electron beams have irradiation position adjustment errors (residual errors);

FIG. 4 is a view showing a drawing data generation method according to the first embodiment;

FIG. 5A is a view showing a drawing result when the irradiation position adjustment error is not corrected;

FIG. 5B is a view showing a drawing result when the irradiation position adjustment error is corrected;

FIG. 6 is a view showing irradiation positions when there are electron beams having nonuniform irradiation position adjustment errors;

FIG. 7 is a view showing a drawing data generation method according to the second embodiment;

FIG. 8 is a view showing irradiation positions when only two electron beams have large irradiation position adjustment errors;

FIG. 9 is a view showing a drawing data generation method according to the third embodiment;

FIG. 10 is a view for explaining the array and scanning of electron beams on a substrate in a 4 (rows)×4 (columns) active matrix driving method;

FIG. 11 is a view showing a drawing method of generating four drawing data in the 4 (rows)×4 (columns) active matrix driving method;

FIG. 12 is a view showing irradiation positions when some electron beams have irradiation position adjustment errors in the 4 (rows)×4 (columns) active matrix driving method; and

FIG. 13 is a view showing a drawing data generation method according to the fourth embodiment.

### DESCRIPTION OF THE EMBODIMENTS

Embodiments of the present invention will now be described with reference to the accompanying drawings.

### First Embodiment

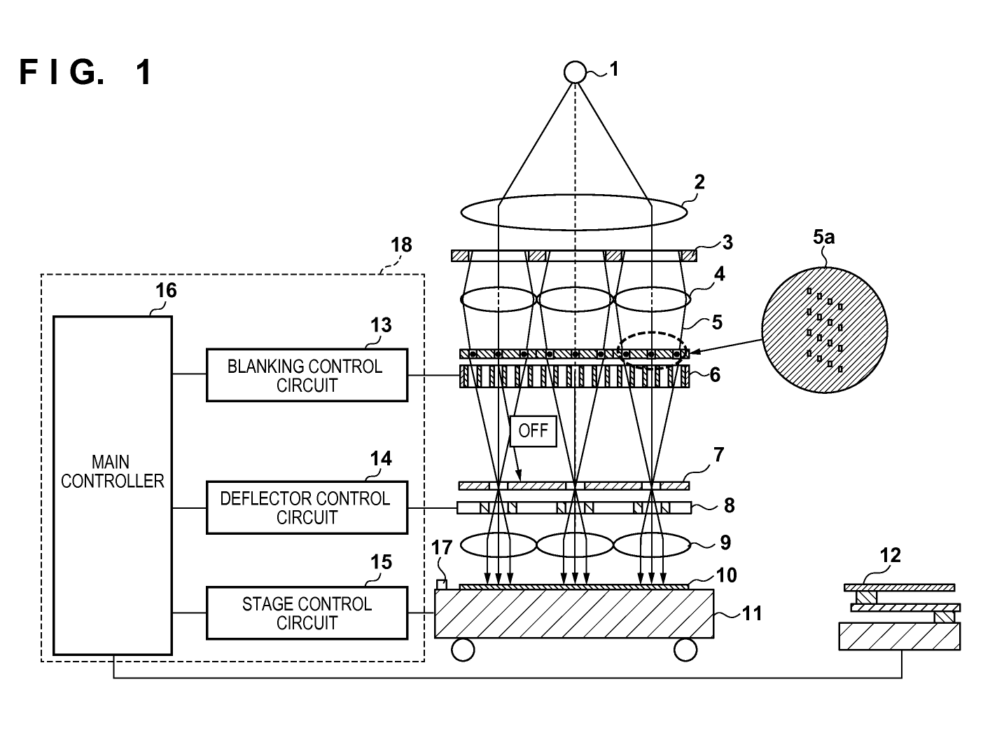

FIG. 1 is a view showing the arrangement of a drawing apparatus which performs drawing on a substrate with a plurality of electron beams. In FIG. 1, a so-called thermoelectron source containing LaB₆, BaO/W (dispenser cathode), or the like as an electron emitting material can be used as an electron source 1. An electrostatic lens which converges an electron beam by an electric field can be used as a collimator lens 2. The collimator lens 2 changes an electron beam emitted by the electron source 1 into an almost parallel electron beam. Note that the drawing apparatus in the following embodiment draws a pattern on a substrate with a plurality of electron beams, but may use a charged particle beam such as an ion beam other than an electron beam. This drawing apparatus can be generalized into a drawing apparatus which draws a pattern on a substrate with a plurality of charged particle beams.

An aperture array 3 has two-dimensionally arrayed openings. In a condenser lens array 4, electrostatic condenser lenses having the same optical power are two-dimensionally arrayed. A pattern opening array 5 includes, in correspondence with the respective condenser lenses, the arrays (sub-arrays) of pattern openings which define (determine) the shape of an electron beam. Reference numeral 5a denotes a shape when the sub-array is viewed from above.

An almost parallel electron beam traveling from the collimator lens 2 is split into a plurality of electron beams by the aperture array 3. The split electron beams irradiate corresponding sub-arrays of the pattern opening array 5 through corresponding condenser lenses of the condenser lens array 4. The aperture array 3 has a function of defining the irradiation range of an electron beam.

In a blanking device (blanker array (BLA)) 6, electrostatic blankers (electrode pairs) capable of individually blanking an electron beam are arrayed in correspondence with the respective condenser lenses. In a blanking aperture array 7, a plurality of openings are arrayed in correspondence with the respective condenser lenses. In a deflector array 8, deflectors configured to deflect an electron beam in a predetermined direction are arrayed in correspondence with the respective condenser lenses. In an objective lens array 9, electrostatic objective lenses are arrayed in correspondence with the respective condenser lenses. The building components from the electron source 1 to the objective lens array 9 constitute an electron optical system (charged particle optical system) which performs drawing on a wafer (substrate) 10 with an electron beam. The electron optical system is also called an irradiation system or projection system.

An electron beam traveling from each sub-array of the pattern opening array 5 is reduced to a size of 1/100 through a corresponding blanker, blanking aperture, deflector, and objective lens, and is projected on the wafer 10. A surface of the sub-array on which pattern openings are arrayed serves as the object plane, and the upper surface of the wafer 10 serves as the image plane.

An electron beam traveling from each sub-array of the pattern opening array 5 is switched under the control of a corresponding blanker between whether to blank the electron beam by the blanking aperture, that is, whether the electron beam is incident on the wafer 10. Parallel to this, an electron beam incident on the wafer 10 is scanned on the wafer in the same deflection amount by the deflector array 8.

The electron source 1 is imaged on the blanking aperture through the collimator lens 2 and condenser lens, and the size of the image is set to be larger than the opening of the blanking aperture. Thus, the semiangle (half angle) of an electron beam on the wafer is defined by the opening of the blanking aperture. The opening of the blanking aperture is arranged at the front focal position of a corresponding objective lens. Hence, the principal rays of a plurality of electron beams having passed through a plurality of pattern openings of the sub-array are incident on the wafer almost perpendicularly. Thus, even if the wafer 10 is displaced vertically, the displacement of the electron beam in the horizontal plane is small.

A stage 11 holds the wafer 10 and is movable within the X-Y plane (horizontal plane) perpendicular to the optical axis. The stage 11 includes a chuck mechanism (not shown) such as an electrostatic chuck for holding (chucking) the wafer 10, and a detector (not shown) which includes an opening pattern on which an electron beam is incident, and detects the position of an electron beam. A conveying mechanism 12 conveys the wafer 10 and transfers the wafer 10 to/from the stage 11.

A blanking control circuit 13 individually controls a plurality of blankers constituting the blanker array 6. Based on a common signal, a deflector control circuit 14 controls a plurality of deflectors constituting the deflector array 8. A stage control circuit 15 controls positioning of the stage 11 in cooperation with a laser interferometer (not shown) which measures the position of the stage 11. A main controller 16 controls the plurality of control circuits described above, and comprehensively controls the drawing apparatus. In the first embodiment, a controller 18 of the drawing apparatus is constituted by the control circuits 13 to 15 and the main controller 16. However, this is merely an example, and the arrangement can be appropriately changed.

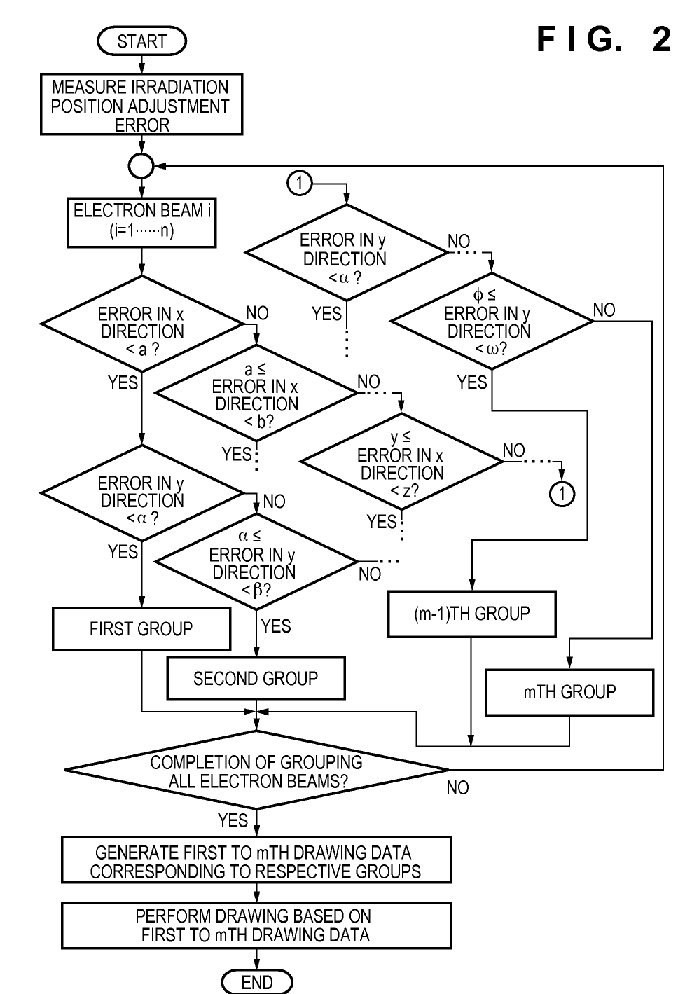

FIG. 2 is a flowchart showing a drawing method according to the embodiment. The drawing method will be explained with reference to this flowchart. First, the adjustment errors (residual errors) of irradiation positions are measured for all electron beams. The adjustment error is a displacement of the irradiation position of each electron beam on the substrate from a target position, and has the direction and magnitude. The adjustment error of the irradiation position of each electron beam on the substrate is measured by, for example, a detector 17 which detects a drawing result and the irradiation position of an electron beam. Then, for each electron beam, the main controller 16 determines whether the adjustment error of the measured irradiation position in the X direction is smaller than an arbitrary value a. If the adjustment error in the X direction is smaller than a, the main controller 16 determines whether the error in the Y direction is smaller than α. If the error in the Y direction is smaller than α, the main controller 16 assigns this electron beam to the first group. That is, the irradiation position adjustment error of an electron beam in the first group is smaller than a in the X direction and smaller than α in the Y direction. If the error in the Y direction is equal to or larger than α, the main controller 16 shifts to the next decision block to determine whether the error in the Y direction is smaller than β. If the error in the Y direction is smaller than β, the main controller 16 assigns this electron beam to the second group. If the error in the Y direction is equal to or larger than β, the main controller 16 shifts to the next decision block.

The main controller 16 sequentially repeats the above-described work for errors in the Y direction and errors in the X direction to group all n electron beams (n is a natural number of two or more) into m groups (m is a natural number of two or more and is smaller than n) (grouping step). The number of groups in the grouping step is adjusted in accordance with the target drawing precision. The number of groups can be set to be equal to or smaller than, for example, half the number of electron beams in consideration of the drawing precision and the burden of holding drawing data. After the end of grouping processing, the main controller 16 generates m drawing data by correcting design data corresponding to target positions so as to cancel adjustment errors in accordance with the magnitudes of the irradiation position adjustment errors for the respective groups (generating step).

The drawing apparatus performs drawing by using the m corrected drawing data generated for the m respective groups in the generating step (drawing step). In the embodiment, the main controller 16 performs all the electron beam grouping step, drawing data generating step, and drawing step in FIG. 2. However, a processing apparatus (computer) other than the main controller 16 may perform the electron beam grouping step and drawing data generating step. That is, the processing apparatus (computer) may execute, based on a program, a drawing data generation method including the electron beam grouping step and drawing data generating step.

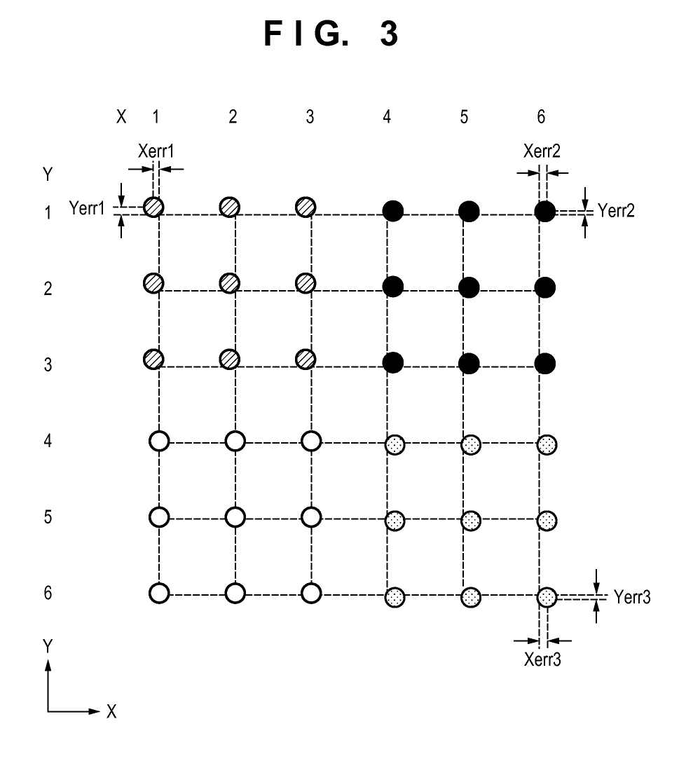

FIG. 3 is a view showing an irradiation position when some electron beams have irradiation position adjustment errors. As for the irradiation positions of 36 electron beams shown in FIG. 3, an upper left electron beam group of X1Y1 to X3Y3 has irradiation position adjustment errors of −Xerr1 in the X-axis direction and Yerr1 in the Y-axis direction. Similarly, an upper right electron beam group of X4Y1 to X6Y3 has adjustment errors of Xerr2 in the X-axis direction and Yerr2 in the Y-axis direction. A lower right electron beam group of X4Y4 to X6Y6 has adjustment errors of Xerr3 in the X-axis direction and −Yerr3 in the Y-axis direction. To the contrary, a lower left electron beam group of X1Y4 to X3Y6 does not have an irradiation position adjustment error. The main controller 16 groups 36 electron beams into four groups according to the sequence shown in FIG. 2. The electron beams X1Y1 to X3Y3 are grouped into the first group, the electron beams X4Y1 to X6Y3 are grouped into the second group, the electron beams X1Y4 to X3Y6 are grouped into the third group, and the electron beams X4Y4 to X6Y6 are grouped into the fourth group.

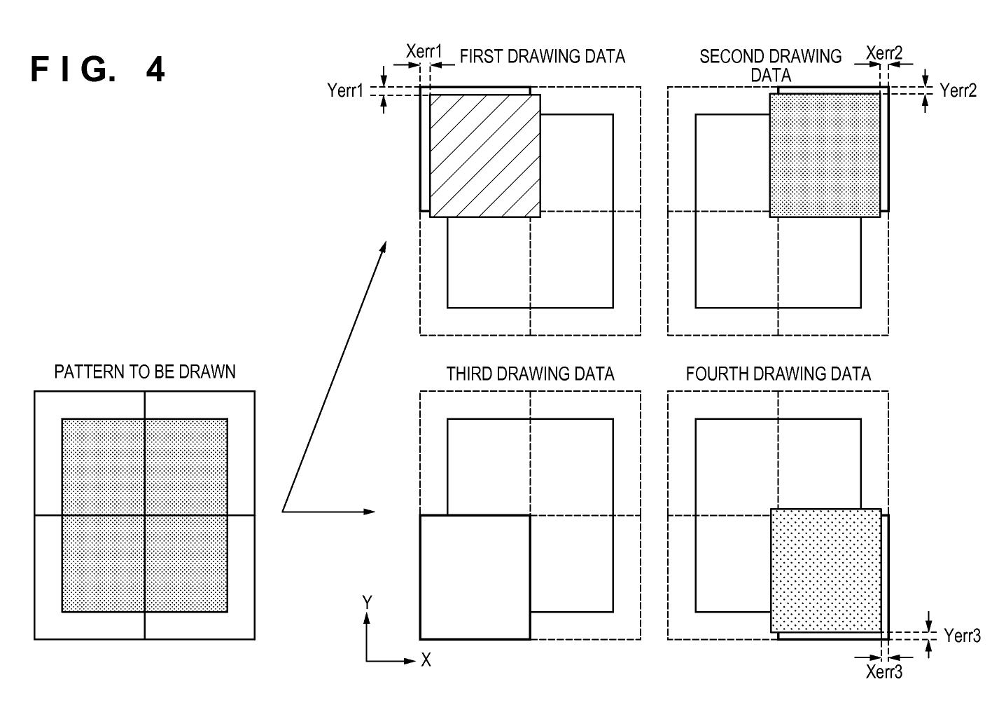

FIG. 4 is a view showing a drawing data generation method according to the first embodiment. The main controller 16 generates the first to fourth drawing patterns for a target drawing pattern (pattern data) by shifting the target drawing pattern so as to cancel the irradiation position adjustment errors of the respective groups. More specifically, drawing data corresponding to the electron beams of the first group in FIG. 3 is the first drawing data obtained by shifting design data corresponding to the target drawing pattern by +Xerr1 in the X-axis direction and −Yerr1 in the Y-axis direction. Similarly, for the electron beams of the second group, the main controller 16 generates the second drawing data by shifting design data corresponding to the target drawing pattern by −Xerr2 in the X-axis direction and −Yerr2 in the Y-axis direction. For the electron beams X1Y4 to X3Y6 of the third group, the main controller 16 generates the third drawing data complying with design data corresponding to the target drawing pattern. For the electron beams of the fourth group, the main controller 16 generates the fourth drawing data by shifting design data corresponding to the target drawing pattern by −Xerr3 in the X-axis direction and +Yerr3 in the Y-axis direction.

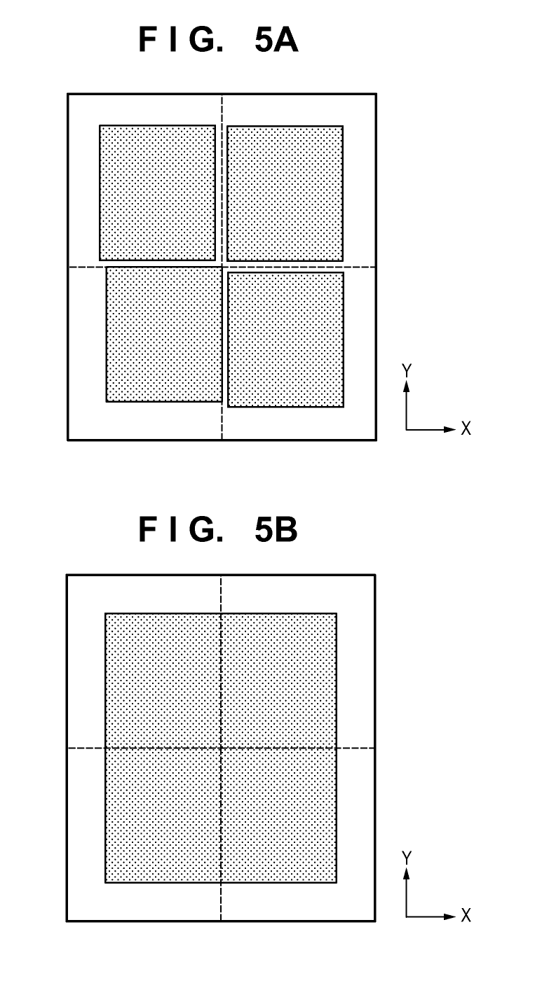

FIGS. 5A and 5B are views showing drawing results when the irradiation position adjustment error is not corrected and is corrected, respectively. FIG. 5A shows a drawing result when drawing is performed using one drawing data corresponding to the target drawing pattern without correcting the irradiation position adjustment error. FIG. 5B shows a drawing result when the electron beams shown in FIG. 3 are grouped into four groups, and drawing is performed using four drawing data obtained by adjusting irradiation positions for the respective group. When one drawing data corresponding to the target drawing pattern is used, the adjustment error of the irradiation position of an electron beam remains, so the target pattern cannot be drawn, as shown in FIG. 5A. In contrast, when the adjustment error of the irradiation position is corrected, the target pattern can be drawn, as shown in FIG. 5B.

### Second Embodiment

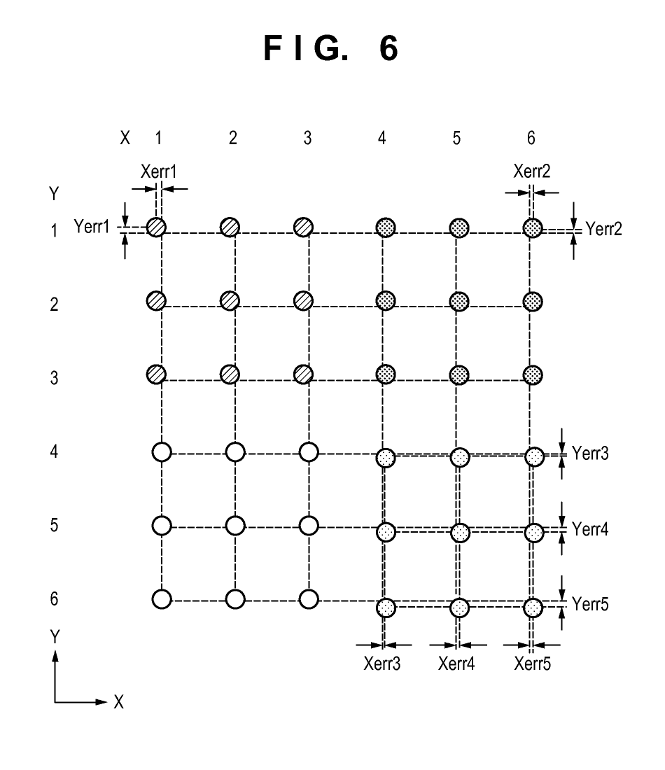

In the first embodiment, the adjustment errors of the irradiation positions of electron beams belonging to the same group have the same value, as shown in FIG. 3. In the second embodiment, the errors of irradiation positions in a group have a plurality of values. FIG. 6 shows the irradiation positions of electron beams when there is a group in which the values of adjustment errors are different though the tendency is the same as that of electron beams in FIG. 3 in which the adjustment errors of irradiation positions in a group have the same value. As for the irradiation positions in FIG. 6, an upper left electron beam group of X1Y1 to X3Y3 has irradiation position adjustment errors of −Xerr1 in the X-axis direction and Yerr1 in the Y-axis direction. An upper right electron beam group of X4Y1 to X6Y3 has adjustment errors of Xerr2 in the X-axis direction and Yerr2 in the Y-axis direction.

Also, a lower left electron beam group of X1Y4 to X3Y6 does not have an irradiation position adjustment error. This is the same as in FIG. 3 so far. However, a lower right electron beam group of X4Y4 to X6Y6 has irradiation position adjustment errors of Xerr3, Xerr4, and Xerr5 in the X-axis direction and −Yerr3, −Yerr4, and −Yerr5 in the Y-axis direction. The values of the adjustment errors Xerr3 to Xerr5 and −Yerr3 to −Yerr5 fall within a range in which they are classified into the same group. When electron beams are grouped according to the sequence shown in FIG. 2, the electron beams X1Y1 to X3Y3 are grouped into the first group, the electron beams X4Y1 to X6Y3 are grouped into the second group, the electron beams X1Y4 to X3Y6 are grouped into the third group, and the electron beams X4Y4 to X6Y6 are grouped into the fourth group.

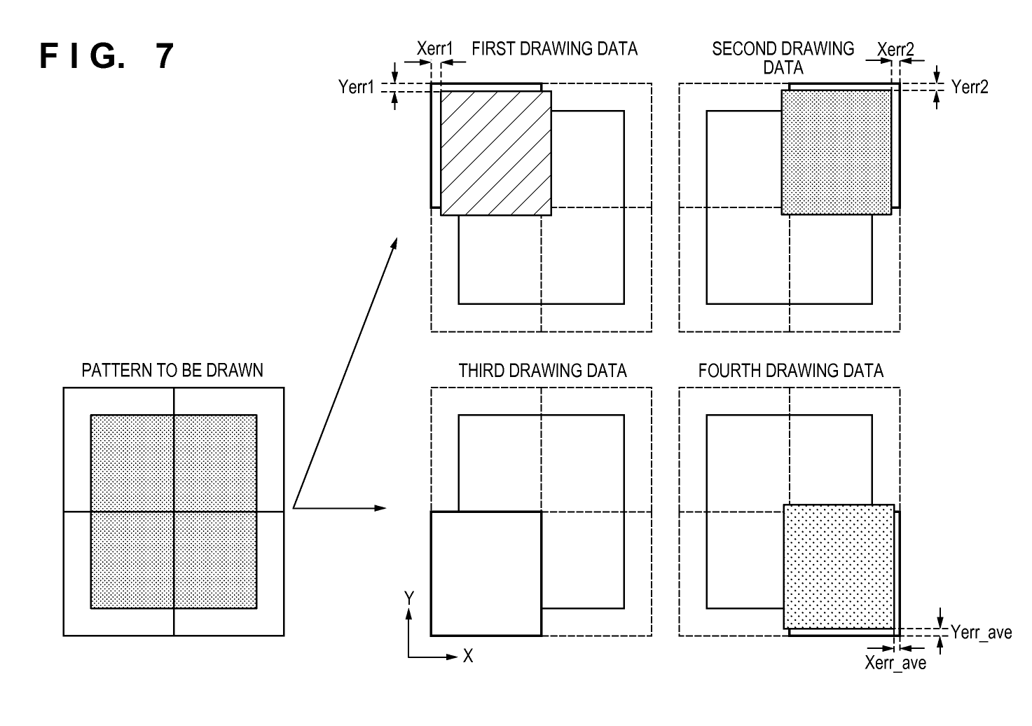

FIG. 7 is a view showing a drawing data generation method according to the second embodiment. A main controller 16 generates the first to fourth drawing patterns for a target drawing pattern by shifting the target drawing pattern so as to cancel the irradiation position adjustment errors of the respective groups. Drawing data corresponding to the electron beams of the first group is the first drawing data obtained by shifting design data corresponding to the target drawing pattern by +Xerr1 in the X-axis direction and −Yerr1 in the Y-axis direction. For the electron beams of the second group, the main controller 16 generates the second drawing data by shifting design data corresponding to the target drawing pattern by −Xerr2 in the X-axis direction and −Yerr2 in the Y-axis direction. For the electron beams X1Y4 to X3Y6 of the third group, the main controller 16 generates the third drawing data complying with design data corresponding to the target drawing pattern.

As for electron beams classified into the fourth group, the irradiation position adjustment errors are not the same. Thus, the main controller 16 decides correction amounts from design data corresponding to the target drawing pattern based on, for example, the average values of the adjustment errors:

Xerr_ave=(Xerr3+Xerr4+Xerr5)×3/9 (1)

Yerr_ave=(Yerr3+Yerr4+Yerr5)×3/9 (2)

The main controller 16 generates the fourth drawing data by shifting design data corresponding to the target drawing pattern by −Xerr_ave in the X-axis direction and Yerr_ave in the Y-axis direction for the electron beams of the fourth group. By performing drawing using the first to fourth generated drawing data, the target pattern can be drawn. When adjustment errors in a group vary, as described above, the shift amount is decided from the average value of the adjustment errors. Therefore, the drawing result can be obtained in a smaller processing amount in comparison with generation of drawing data for each electron beam. In the second embodiment, drawing data is generated using the average value of irradiation position adjustment errors. However, drawing data may be generated using a method such as the least-square method.

### Third Embodiment

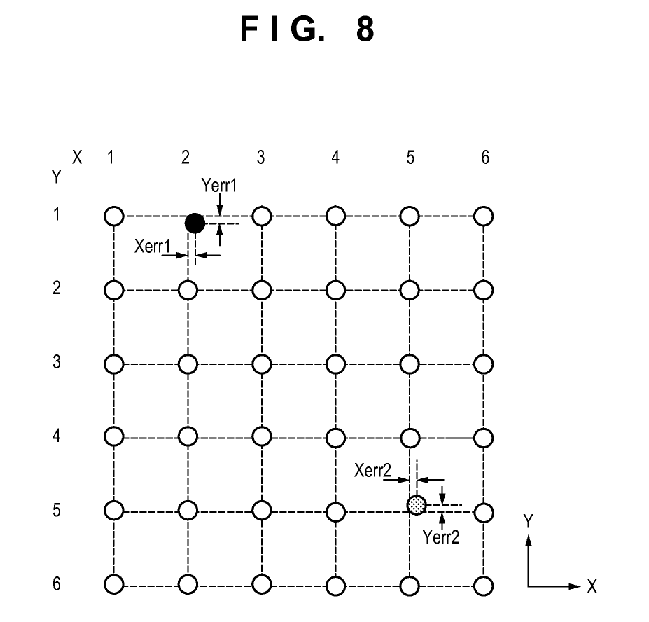

In the third embodiment, electron beams have large irradiation position adjustment errors sporadically. FIG. 8 shows irradiation positions when only two of 36 electron beams have large irradiation position adjustment errors. An electron beam X2Y1 has irradiation position adjustment errors of Xerr1 in the X-axis direction and −Yerr1 in the Y-axis direction. An electron beam X5Y5 has irradiation position adjustment errors of Xerr2 in the X-axis direction and Yerr2 in the Y-axis direction. The remaining electron beams do not have irradiation position adjustment errors. In this case, according to the sequence shown in FIG. 2, the electron beam X2Y1 can be grouped into the first group, the electron beam X5Y5 can be grouped into the second group, and the remaining electron beams can be grouped into the third group.

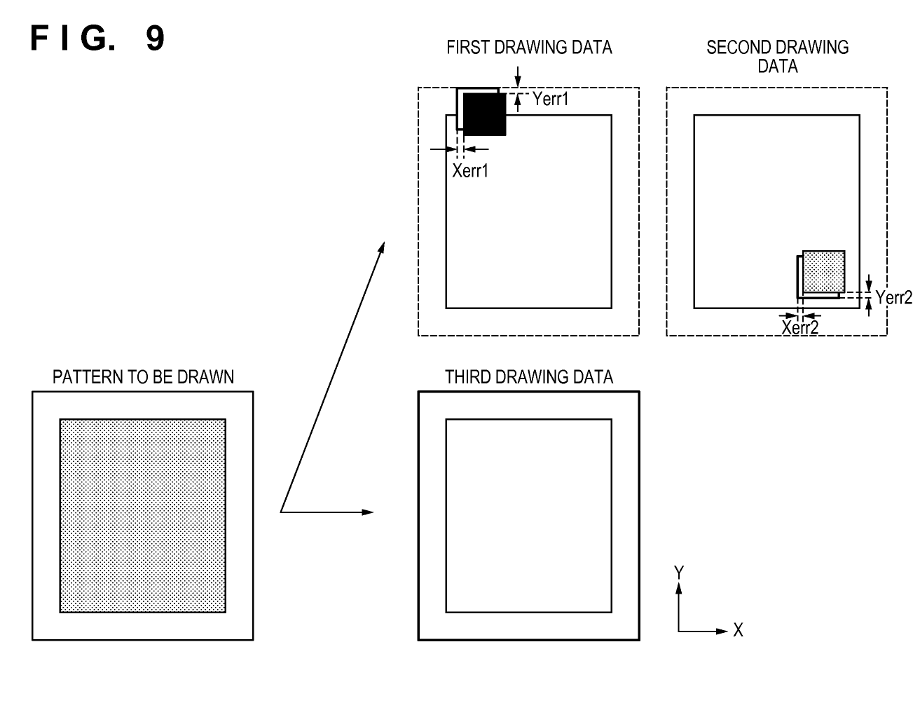

FIG. 9 is a view showing a drawing data generation method according to the third embodiment. A main controller 16 generates the first to third drawing patterns for a target drawing pattern by shifting the target drawing pattern so as to cancel the irradiation position adjustment errors of the respective groups. For the electron beam of the first group, the main controller 16 generates the first drawing data by shifting design data corresponding to the target drawing pattern by −Xerr1 in the X-axis direction and +Yerr1 in the Y-axis direction. For the electron beam of the second group, the main controller 16 generates the second drawing data by shifting design data corresponding to the target drawing pattern by −Xerr2 in the X-axis direction and −Yerr2 in the Y-axis direction. For the electron beams of the third group, the main controller 16 generates the third drawing data complying with design data corresponding to the target drawing pattern. By performing drawing using the first to third generated drawing data, the main controller 16 can draw the target pattern.

### Fourth Embodiment

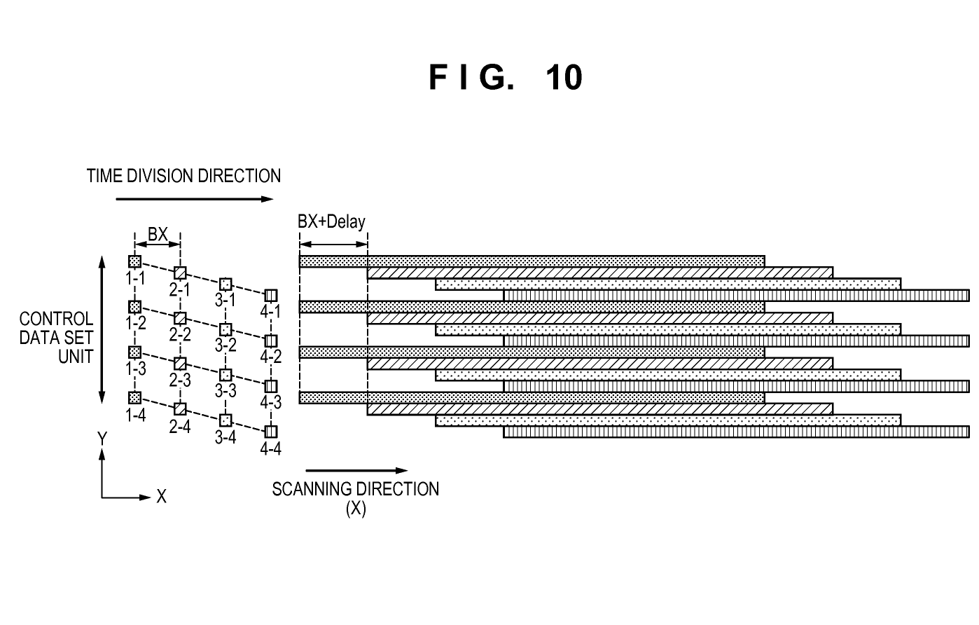

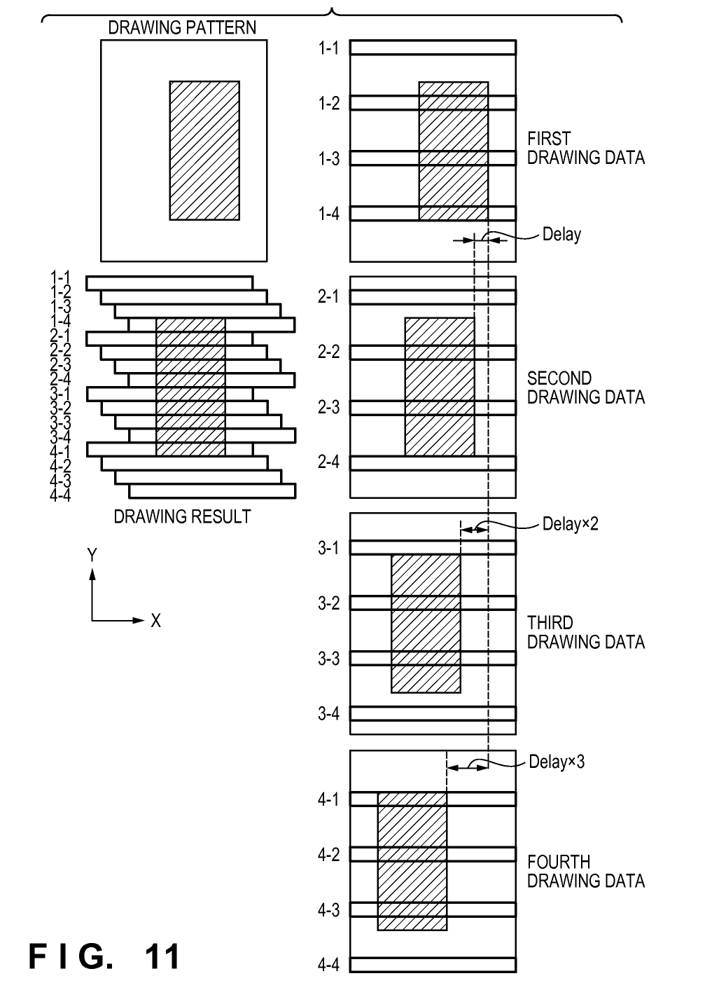

The fourth embodiment will describe a case in which the present invention is applied to a drawing apparatus including an active matrix driving blanker. FIG. 10 is a view for explaining the array and scanning of electron beams irradiating a substrate in a 4 (rows)×4 (columns) active matrix driving method. FIG. 11 is a view showing a drawing method of generating four drawing data in the 4 (rows)×4 (columns) active matrix driving method.

In the 4 (rows)×4 (columns) active matrix driving method shown in FIG. 10, blanker control data are set at the same timing for respective blankers in the Y-axis direction. Four blankers 1-1 to 1-4 in the Y-axis direction for which blanker control data are set at the same timing form the first blanker group. Four blankers 2-1 to 2-4 adjacent in the X-axis direction form the second blanker group. Blankers sequentially form the third blanker group and fourth blanker group. In the active matrix driving method, electron beams are scanned in the scanning grid direction even while the blanking state is set sequentially by time division, as shown in FIG. 10.

As shown in FIG. 11, a main controller 16 calculates a scanning start position difference Delay from the scanning speed and the time difference of the control data setting timing. In this case, the main controller 16 can generate the second, third, and fourth drawing data by shifting left the first drawing data of the first blanker group by Delay×1, Delay×2, and Delay×3, respectively. The first to fourth drawing data correspond to the first to fourth blanker groups, respectively. A blanking control circuit 13 extracts part of each drawing data in accordance with the Y position to generate blanker control data, thereby correcting the time difference of the control data setting timing by the active matrix driving method.

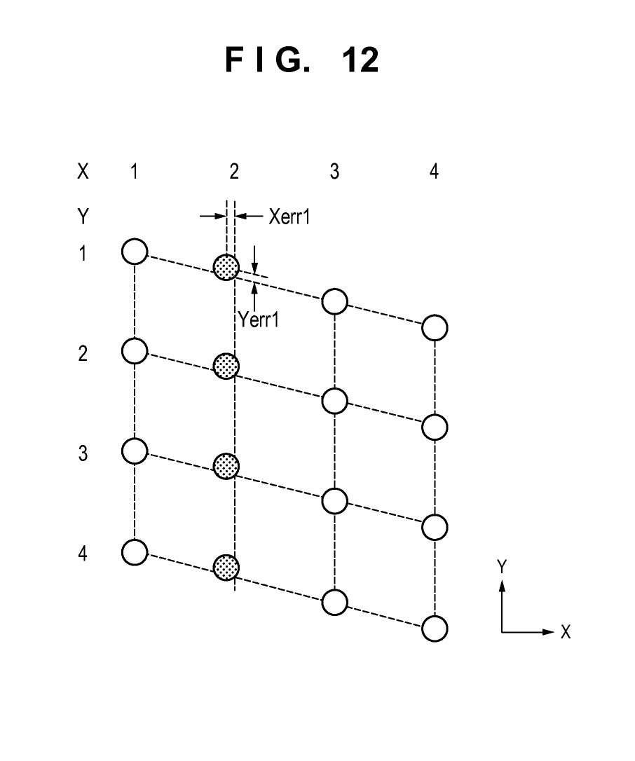

FIG. 12 shows the irradiation positions of electron beams when some electron beams have irradiation position adjustment errors in the 4 (rows)×4 (columns) active matrix driving method. As for the irradiation positions in FIG. 12, electron beams X2Y1 to X2Y4 corresponding to blanker group 2 have irradiation position adjustment errors of −Xerr1 in the X-axis direction and Yerr1 in the Y-axis direction. The remaining electron beams do not have adjustment errors.

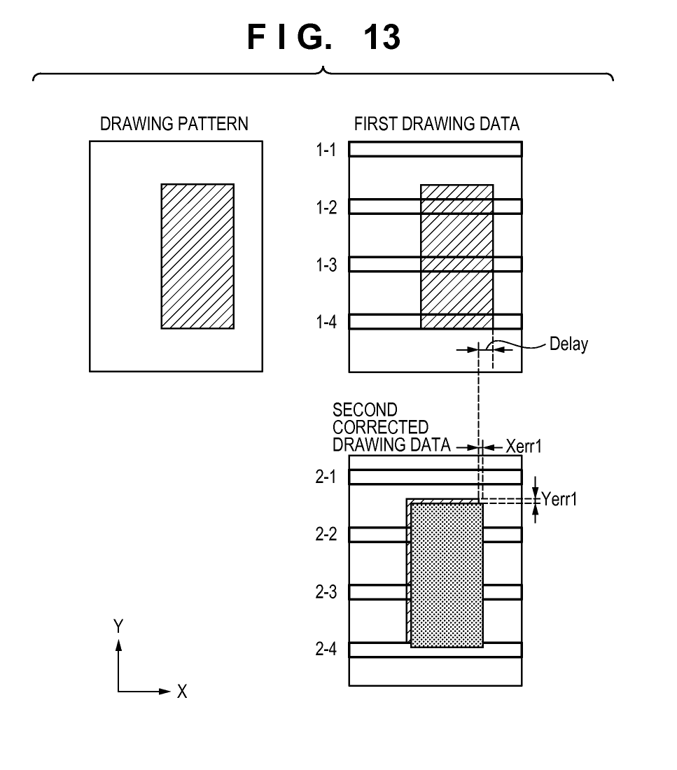

FIG. 13 is a view showing a drawing data generation method for the electron beams shown in FIG. 12. The electron beams X2Y1 to X2Y4 have irradiation position adjustment errors of Xerr1 in the X-axis direction and Yerr1 in the Y-axis direction. Hence, the main controller 16 generates the second corrected drawing data obtained by shifting the second drawing data in FIG. 12 by +Xerr1 in the X-axis direction and −Yerr1 in the Y-axis direction. By performing drawing using the first generated drawing pattern, the second corrected drawing pattern, and the third and fourth drawing patterns, the target pattern can be drawn. In the embodiment, the adjustment error of an irradiation position by the electron optical system is corrected. However, when a large adjustment error correction range is ensured, a mechanism of correcting the irradiation position of an electron beam, for example, a deflector can be omitted to simplify the electron optical system and reduce the cost.

### Fifth Embodiment

A method of manufacturing an article according to an embodiment of the present invention is suitable for manufacturing an article such as a microdevice (for example, a semiconductor device) or an element having a microstructure. The manufacturing method can include a step of forming a latent image pattern on the photosensitive agent of a substrate coated with the photosensitive agent by using the above-described drawing apparatus (a step of performing drawing on a substrate), and a step of developing the substrate on which the latent image pattern has been formed in the preceding step. Further, the manufacturing method can include other well-known steps (for example, oxidization, deposition, vapor deposition, doping, planarization, etching, resist removal, dicing, bonding, and packaging). The method of manufacturing an article according to the embodiment is superior to a conventional method in at least one of the performance, quality, productivity, and production cost of the article.

### Other Embodiments

Embodiments of the present invention can also be realized by a computer of a system or apparatus that reads out and executes computer executable instructions recorded on a storage medium (e.g., non-transitory computer-readable storage medium) to perform the functions of one or more of the above-described embodiment(s) of the present invention, and by a method performed by the computer of the system or apparatus by, for example, reading out and executing the computer executable instructions from the storage medium to perform the functions of one or more of the above-described embodiment(s). The computer may comprise one or more of a central processing unit (CPU), micro processing unit (MPU), or other circuitry, and may include a network of separate computers or separate computer processors. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2013-166993, filed Aug. 9, 2013, which is hereby incorporated by reference herein in its entirety.

What is claimed is:

1. A method of generating drawing data for performing drawing on a substrate with a plurality of charged particle beams based on pattern data representing a pattern to be drawn on the substrate, the method comprising:
a grouping step of grouping the plurality of charged particle beams into a plurality of groups based on a displacement amount of an irradiation position of each of the plurality of charged particle beams from a target position thereof; and
a generating step of generating the drawing data by changing the pattern data with respect to each of the plurality of groups based on the displacement amount of each of the plurality of charged particle beams.

2. The method according to claim 1, wherein the generating step changes the pattern data based on an average value of a plurality of the displacement amount with respect to each of the plurality of groups.

3. The method according to claim 1, wherein the grouping step groups the plurality of charged particle beams into the plurality of groups based on a target drawing precision.

4. The method according to claim 1, wherein number of groups constituting the plurality of groups is not greater than half of number of charged particle beams constituting the plurality of charged particle beams.

5. A processing apparatus for generating drawing data for performing drawing on a substrate with a plurality of charged particle beams based on pattern data representing a pattern to be drawn on the substrate, wherein the apparatus is configured to perform:
a grouping processing of grouping the plurality of charged particle beams into a plurality of groups based on a displacement amount of an irradiation position of each of the plurality of charged particle beams from a target position thereof; and
a generating processing of generating the drawing data by changing the pattern data with respect to each of the plurality of groups based on the displacement amount of each of the plurality of charged particle beams.

6. A storage medium which stores a program for causing a computer to execute a method of generating drawing data for performing drawing on a substrate with a plurality of charged particle beams based on pattern data representing a pattern to be drawn on the substrate, the method comprising:
a grouping step of grouping the plurality of charged particle beams into a plurality of groups based on a displacement amount of an irradiation position of each of the plurality of charged particle beams from a target position thereof; and
a generating step of generating the drawing data by changing the pattern data with respect to each of the plurality of groups based on the displacement amount of each of the plurality of charged particle beams.

7. A drawing apparatus for performing drawing on a substrate with a plurality of charged particle beams based on drawing data, the apparatus comprising:
a processing apparatus configured to generate the drawing data based on pattern data representing a pattern to be drawn on the substrate,
wherein the processing apparatus is configured to perform:
a grouping processing of grouping the plurality of charged particle beams into a plurality of groups based on a displacement amount of an irradiation position of each of the plurality of charged particle beams from a target position thereof; and
a generating processing of generating the drawing data by changing the pattern data with respect to each of the plurality of groups based on the displacement amount of each of the plurality of charged particle beams.

8. The apparatus according to claim 7, further comprising:
a blanking device configured to individually blank the plurality of charged particle beams; and
a controller configured to control the blanking device based on the drawing data with respect to each of the plurality of groups.

9. The apparatus according to claim 7, further comprising a detector configured to obtain the displacement amount.

10. A method of manufacturing an article, the method comprising steps of:
performing drawing on a substrate using a drawing apparatus for performing drawing on a substrate with a plurality of charged particle beams based on drawing data;
developing the substrate on which the drawing has been performed; and
processing the developed substrate to manufacture the article,
wherein the drawing apparatus includes:
a processing apparatus configured to generate the drawing data based on pattern data representing a pattern to be drawn on the substrate,
wherein the processing apparatus is configured to perform:
a grouping processing of grouping the plurality of charged particle beams into a plurality of groups based on a displacement amount of an irradiation position of each of the plurality of charged particle beams from a target position thereof; and
a generating processing of generating the drawing data by changing the pattern data with respect to each of the plurality of groups based on the displacement amount of each of the plurality of charged particle beams.
